(19) United States
(12) Patent Application Publication
(10) Pub. No.: US 2024/0178155 A1
(43) Pub. Date: May 30, 2024

(54) MULTILEVEL PACKAGE SUBSTRATE WITH BOX SHIELD

(71) Applicant: Texas Instruments Incorporated, Dallas, TX (US)

(72) Inventors: Yiqi Tang, Allen, TX (US); Chittranjan Mohan Gupta, Richardson, TX (US); Rajen Manicon Murugan, Dallas, TX (US); Jie Chen, Plano, TX (US)

(21) Appl. No.: 18/071,972

(22) Filed: Nov. 30, 2022

(51) Int. Cl. H01L 23/552; H01L 21/48; H01L 23/00; H01L 23/498

(52) U.S. Cl. CPC H01L 23/552; H01L 21/4839; H01L 23/49822; H01L 23/49838; H01L 23/49861; H01L 24/16; H01L 2224/16235; H01L 2924/3025

(57) ABSTRACT

An electronic device includes a multilevel package substrate having a first level, a second level, a third level, a conductive signal trace that extends in the second level, and a conductive box shield that surrounds a portion of the conductive signal trace. The electronic device includes a semiconductor die attached to the multilevel package substrate and having a conductive structure coupled to an end of the conductive signal trace. The electronic device includes a package structure that encloses the semiconductor die and a portion of the multilevel package substrate.

### BACKGROUND

Low crosstalk and electromagnetic interference (EMI) performance are important for high speed electronic devices and systems, such as flat panel display link (FPD-Link) or other high speed digital video interface circuits, radio frequency (RF) amplifiers, high speed multiplexers, etc. Low EMI emissions and crosstalk immunity are more difficult with addition of multi-channel capability and higher IO counts in these devices, particularly for small form factor devices in compact system designs. Stitching via arrays can provide some benefits to shield electric fields and reduce crosstalk, but the array of drilled vias leak electrical field and do not provide a complete solution for EMI and crosstalk performance.

### SUMMARY

In one aspect, an electronic device includes a multilevel package substrate, a semiconductor die, and a package structure. The multilevel package substrate has a first level, a second level, a third level, a conductive signal trace that extends in the second level, and a conductive box shield that surrounds a portion of the conductive signal trace. The semiconductor die attached is to the multilevel package substrate and has a conductive structure coupled to an end of the conductive signal trace. The package structure encloses the semiconductor die and a portion of the multilevel package substrate.

In another aspect, a multilevel package substrate includes a first level, a second level on the first level and having a conductive signal trace, a third level on the second level, and a conductive box shield including contiguous conductive metal structures of the first, second, and third levels that surround a portion of the conductive signal trace.

In a further aspect, a method of fabricating an electronic device includes forming first, second, and third levels of a multilevel package substrate having a conductive box shield that surrounds a portion of a conductive signal trace and includes a shield top, a shield bottom, and opposite first and second shield sidewalls. Forming the first level includes: forming a first trace layer with patterned first conductive trace features, the shield top including a portion of a first one of the first conductive trace features; forming a first via layer with patterned first conductive via features on the first conductive trace features; and forming a first dielectric layer on and between the first conductive trace features and between the first conductive via features. Forming the second level includes: forming a second trace layer with patterned second conductive trace features on the first conductive via features and on the first dielectric layer, the first shield sidewall including a portion of a first one of the patterned second conductive trace features, the second shield sidewall including a portion of a second one of the patterned second conductive trace features, the conductive signal trace includes a third one of the patterned second conductive trace features: forming a second via layer with patterned second conductive via features on the second conductive trace features, the first shield sidewall including a portion of a first one of the second conductive via features, the second shield sidewall including a portion of a second one of the second conductive via features; and forming a second dielectric layer on and between the second conductive trace features and between the second conductive via features. Forming the third level includes: forming a third trace layer with patterned third conductive trace features on the second conductive via features and on the second dielectric layer, the shield bottom including a portion of a first one of the third conductive trace features; and forming a third dielectric layer on and between the third conductive trace features.

### BRIEF DESCRIPTION OF THE DRAWINGS

FIG. 1 is a top perspective view of an electronic device with a box shield in a multilevel package substrate.

FIG. 1A is a bottom perspective view of the electronic device of FIG. 1.

FIG. 1B is a sectional side elevation view of the electronic device taken along line 1B-1B in FIG. 1.

FIG. 1C is a partial sectional side elevation view of the electronic device taken along line 1C-1C in FIG. 1D.

FIG. 1D is a sectional top view of the electronic device taken along line 1D-1D in FIG. 1C.

FIG. 1E is a partial perspective view of a box shield in the multilevel package substrate of the electronic device of FIGS. 1-1D.

FIG. 1F is a partial top view of a box shield in the multilevel package substrate of the electronic device of FIGS. 1-1E.

FIG. 1G is a partial perspective view of two box shields in the multilevel package substrate of the electronic device of FIGS. 1-1E.

FIG. 2 is a flow diagram of a method of fabricating an electronic device with a box shield in a multilevel package substrate.

FIGS. 3-9 show the electronic device of FIGS. 1-1G undergoing fabrication processing according to the method of FIG. 2.

FIG. 10 is a graph of crosstalk performance.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating.

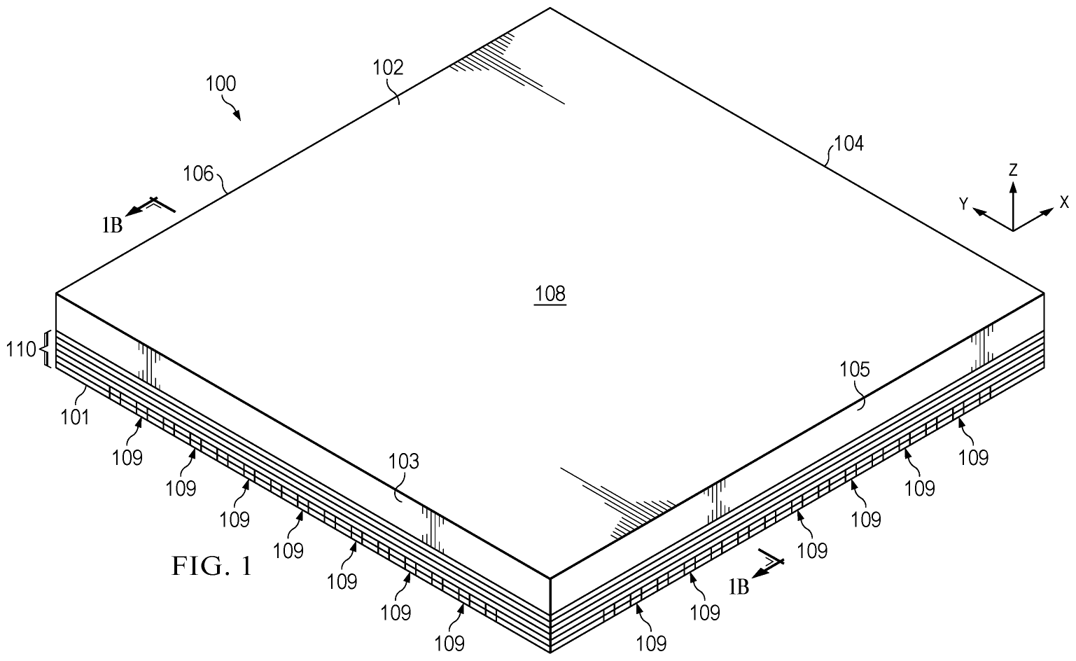

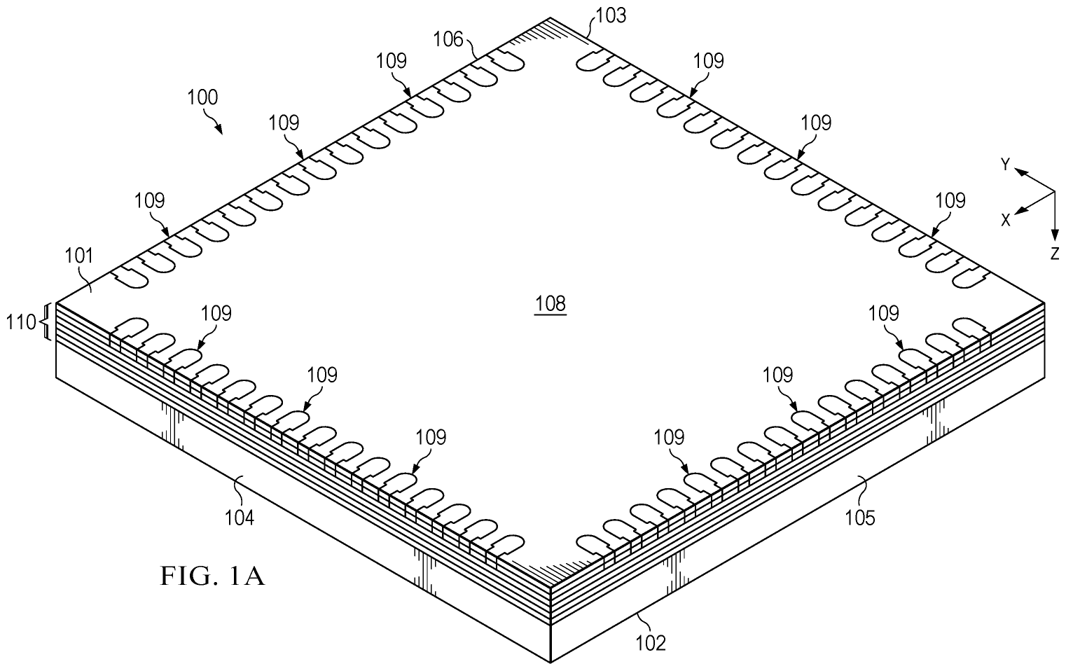

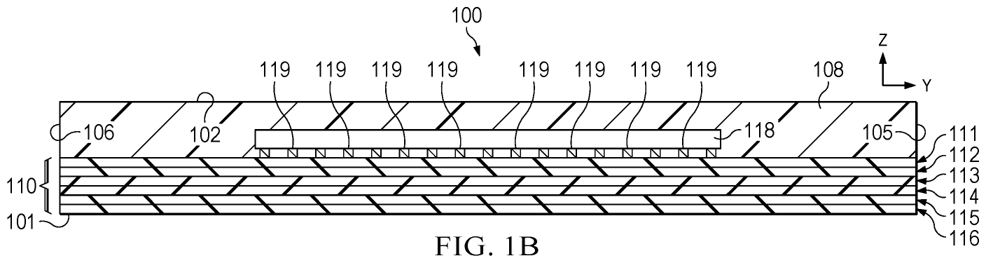

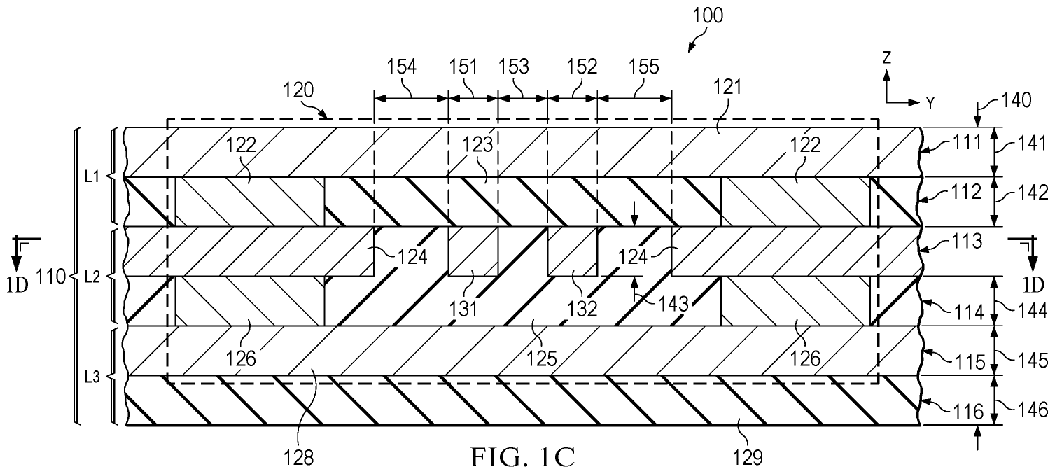

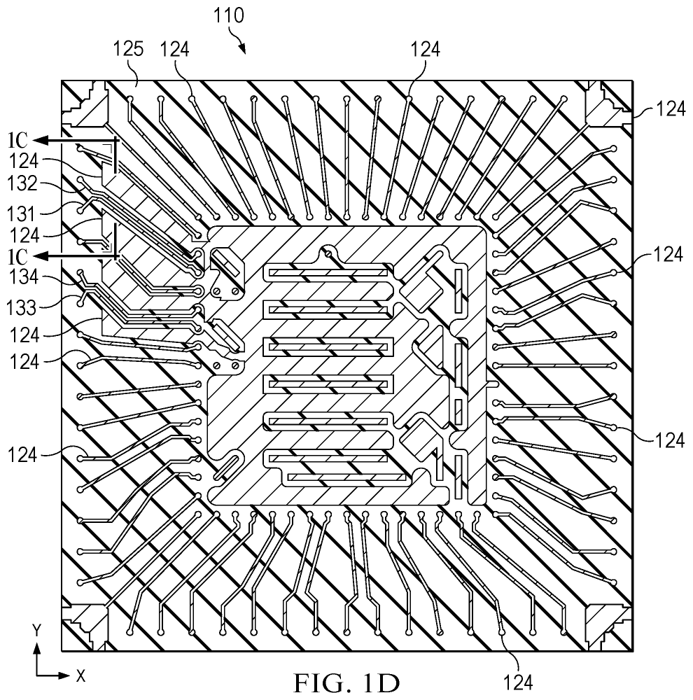

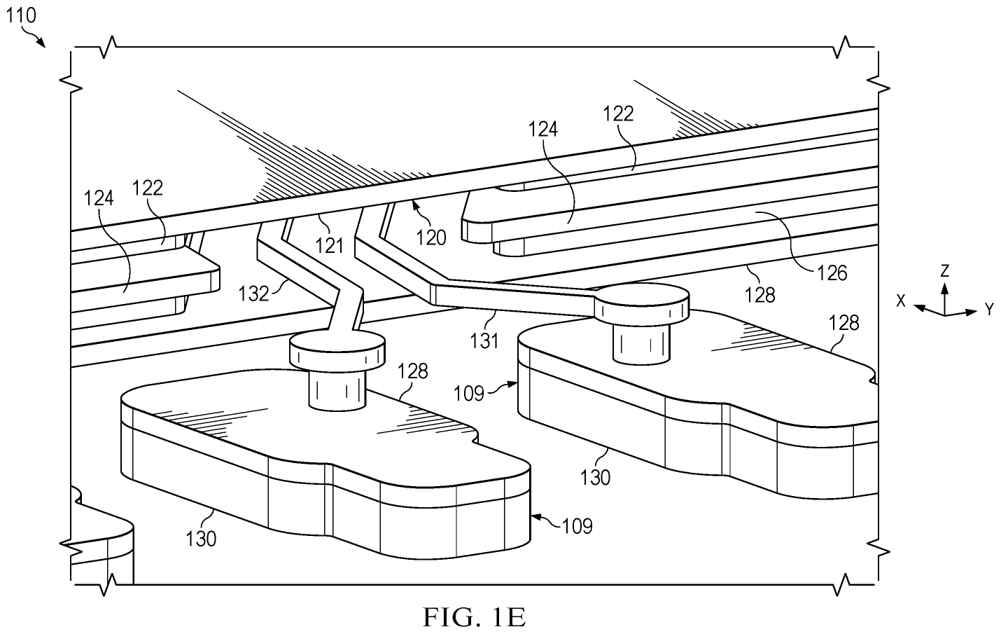

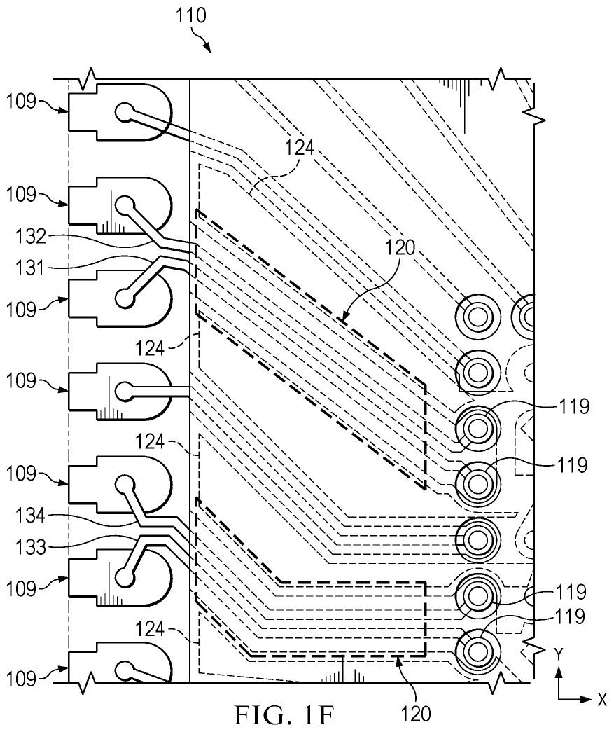

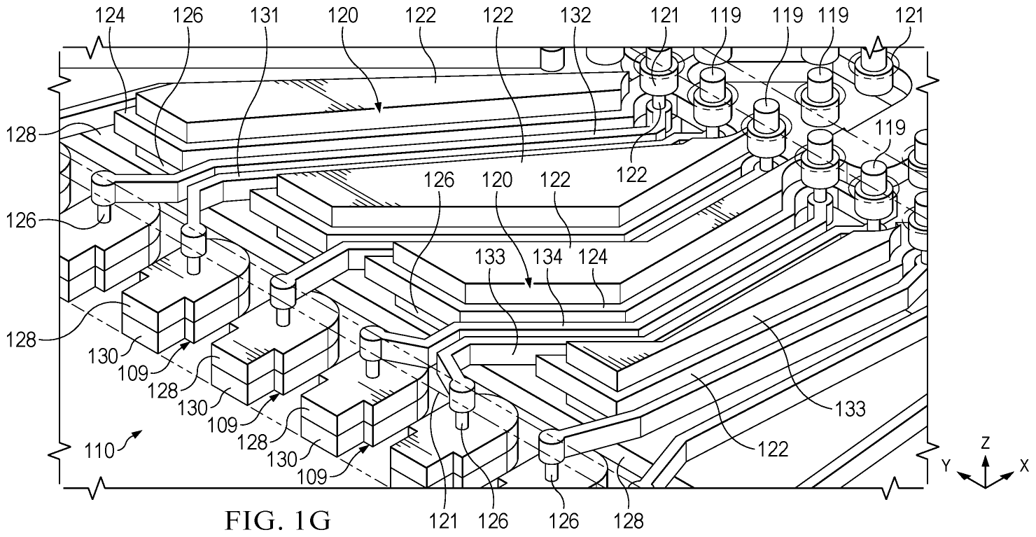

FIGS. 1-1G show an electronic device 100 with a contiguous metal box shield 120 that surrounds a portion of one or more signal traces in a multilevel package substrate 110 and provides a solution for high speed circuits with low crosstalk and low EMI (e.g., to −60 dB and beyond) along with high IO count and compact package size for high speed digital video interface circuits, RF amplifiers, high speed multiplexers, and other high speed circuit applications. Described examples provide performance benefits similar to coaxial cables using a lateral metal box transmission line structure integrated in the multilevel package substrate to meet applicable low crosstalk and EMI requirements for a given system design.

FIGS. 1 and 1A show respective top and bottom perspective views, FIG. 1B shows a sectional side view taken along line 1B-1B in FIG. 1, FIG. 1C shows a partial sectional side view along line 1C-1C in FIG. 1D, and FIG. 1D shows a sectional top view along line 1D-1D in FIG. 1C. FIG. 1E shows a partial perspective view of a box shield in the multilevel package substrate, FIG. 1F is a partial top view of the box shield, and FIG. 1G is a partial perspective view of two box shields in the multilevel package substrate of the electronic device 100. The electronic device 100 is shown in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another.

The electronic device 100 includes a semiconductor die 118 (FIG. 1B) enclosed by a package structure 108, such as a molded plastic. As best shown in FIGS. 1 and 1A, the electronic device 100 has conductive leads 109 (e.g., copper, aluminum, or other conductive metal) exposed on the bottom and four lateral sides. The electronic device has opposite first and second (e.g., bottom and top) sides 101 and 102, respectively, which are spaced apart from one another along the third direction Z. The package structure 108 and the electronic device 100 have laterally opposite third and fourth sides 103 and 104 spaced apart from one another along the first direction X, and opposite fifth and sixth sides 105 and 106 spaced apart from one another along the second direction Y in the illustrated orientation. The sides 101-106 in one example have substantially planar outer surfaces. In other examples, one or more of the sides 101-106 have curves, angled features, or other non-planar surface features.

The semiconductor die 118 has conductive features 119 (FIGS. 1B, 1F, and 1G), such as aluminum or coper bond pads or pillars or solder balls that are mechanically attached to, and form electrical connections to, conductive metal features of a multilevel package substrate 110. The semiconductor die 118 includes one or more electronic components, such as a high speed digital video interface circuit, RF amplifier, high speed multiplexer, or other high speed circuitry. The circuitry of the semiconductor die 118 is electrically coupled to conductive metal features of the multilevel package substrate 110 to form an integrated circuit (IC) electronic device 100. As shown in FIGS. 1-1B, the package structure 108 encloses the semiconductor die 118 and a top side of the multilevel package substrate 110.

As best shown in FIG. 1C, the multilevel package substrate 110 has a first level L1, a second level L2 on (e.g., below) the first level L1, and a third level L3 on (e.g., below) the second level L2. In other examples, the multilevel package substrate 110 can have more than three levels. The individual levels L1-L3 extend in respective planes of the first and second directions (e.g., X-Y planes) and include conductive metal trace and via features as well as dielectric material therebetween. The trace and via features are or include copper, aluminum or other conductive metal or combinations thereof. The first level L1 includes a first trace layer 111 with patterned first conductive trace features 121. The first level L1 includes a first via layer 112 with patterned first conductive via features 122. The first level L1 also includes a first dielectric layer 123 that extends on and between the first conductive trace features 121 and between the first conductive via features 122.

The second level L2 includes a second trace layer 113 with patterned second conductive trace features 124, including a first conductive signal trace 131 and a second conductive signal trace 132, portions of which are surrounded by the conductive metal box shield 120. The second level L2 also includes a second via layer 114 with patterned second conductive via features 126, and a second dielectric layer 125 that extends on and between the second conductive trace features 124, 131, 132 and between the second conductive via features 126. The third level L3 includes a third trace layer 115 with patterned third conductive trace features 128, and a third dielectric layer 129 that extends on and between the third conductive trace features 128. In the illustrated example, the third level L3 also includes a third via layer 116 with patterned third conductive via features 130 (FIG. 1G), and the third dielectric layer 129 extends between the third conductive via features 130. In other implementations, the third via layer 116 can be omitted.

In the example shown in FIG. 1C, the multilevel package substrate 110 has a nominal thickness 140 along the third direction Z of approximately 200 μm in a manufacturing range of approximately 170 μm to approximately 230 μm. In this example, the first conductive trace features 121 of the first trace layer 111 have thicknesses 141 along the third direction Z of in a range of 20 μm to 45 μm, such as approximately 25 μm, and an etch-back thickness 142 of the first conductive via features 122 and the first dielectric layer 123 along the third direction Z is approximately 45 μm. In the second level L2 in this example, the second conductive trace features 124, 131, and 132 of the second trace layer 113 have thicknesses 143 along the third direction Z of in a range of 20 μm to 45 μm, such as approximately 25 μm. An etch-back thickness 144 of the second conductive via features 126 and the second dielectric layer 125 along the third direction Z is approximately 45 μm. In the third level L3, the third conductive trace features 128 of the third trace layer 115 have thicknesses 145 along the third direction Z of in a range of 20 μm to 45 μm, such as approximately 25 μm, and an etch-back thickness 146 of the third conductive via features 130 (FIG. 1E) and the third dielectric layer 129 along the third direction Z is approximately 45 μm.

The illustrated example is configured to carry a differential signal by the first conductive signal trace 131 and the second conductive signal trace 132 in the conductive box shield 120 that surrounds portions of the conductive signal traces 131 and 132. As shown in FIG. 1C, the first conductive signal trace 131 has a width 151 along the second direction Y of approximately 25 μm and the second conductive signal trace 132 has a width 152 along the second direction Y of approximately 25 μm. The conductive signal traces 131 and 132 are spaced apart from one another by a spacing distance 153 along the second direction Y of approximately 75 μm or more. The first conductive signal trace 131 in this example is spaced apart from a first shield sidewall by a spacing distance 154 along the second direction Y of approximately 75 μm or more, and the second conductive signal trace 132 is spaced apart from a second shield sidewall by a spacing distance 155 along the second direction Y of approximately 75 μm or more. The sidewall vias 122 and 126 and the sidewall trace features 124 in this example have a thickness along the second direction Y of approximately 80 μm or more.

As further shown in FIGS. 1D, 1F, and 1G, the illustrated electronic device 100 and the multilevel package substrate 110 include a second differential channel with conductive signal traces 133 and 134 surrounded by a second conductive box shield 120 that surrounds portions of the conductive signal traces 133 and 134. In this example, the channel including the second conductive box shield 120 is similarly constructed and has the same or similar dimensions to the conductive signal traces 131 and 132 and conductive box shield 120 shown in FIG. 1C.

In another implementation (not shown), the multilevel package substrate 110 has a conductive box shield with a single signal trace surrounded by the conductive box shield and configured to carry a single-ended signal. In this implementation, the single signal trace has a width along the second direction Y of approximately 30 μm and is spaced apart from the shield sidewalls by a spacing distance of approximately 50 μm or more. Other dimensions can be used, for example, to tailor the shielding effectiveness, the signal trace current carrying capability, and/or to accommodate manufacturing tolerances.

As further shown in FIGS. 1C-1G, the conductive structures 119 (FIGS. 1F and 1G) of the semiconductor die 118 are attached (e.g., soldered) to conductive trace features on the top side of the multilevel package substrate 110 and are electrically coupled to first ends of respective ones of the conductive signal traces 131, 132, 133, and 134. As shown in FIGS. 1E-1G, conductive leads 109 of the multilevel package substrate 110 are electrically coupled to second ends of the respective conductive signal traces 131, 132, 133, and 134. As shown in FIGS. 1E and 1G, the leads 109 in the illustrated example include respective third conductive via features 130 and respective third conductive trace features 128 of the third level L3.

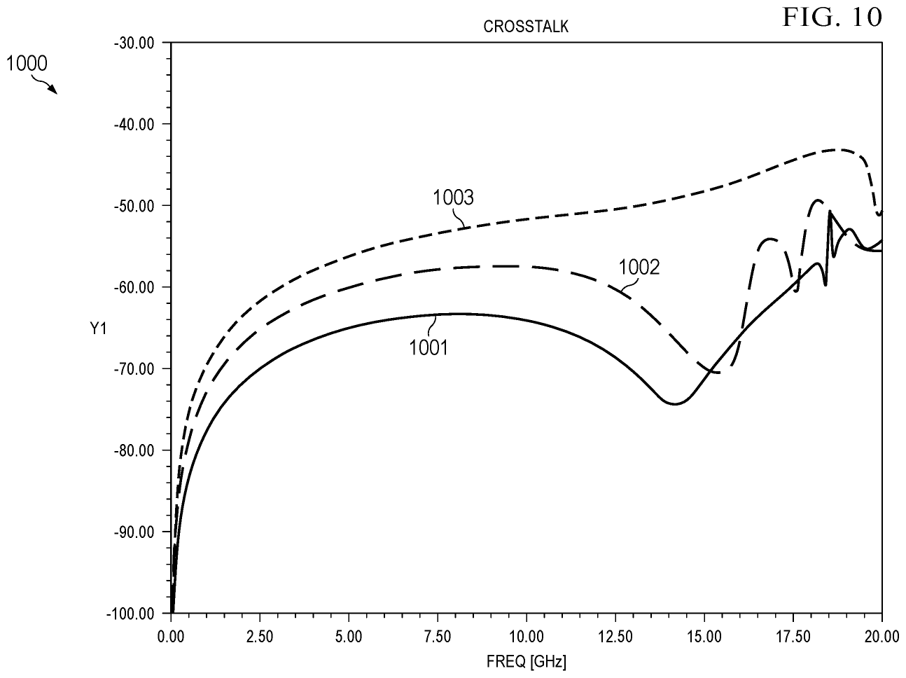

The example conductive box shields 120 each include contiguous conductive metal structures that form a shield top, a shield bottom, and opposite first and second shield sidewalls. As best shown in FIGS. 1C and 1E, the shield top includes a portion of a first one of the first conductive trace features 121 and the shield bottom includes a portion of a first one of the third conductive trace features 128. The first shield sidewall in this example includes a portion of a first one of the first conductive via features 122, a portion of a first one of the patterned second conductive trace features 124, and a portion of a first one of the second conductive via features 126. The second shield sidewall includes a portion of a second one of the first conductive via features 122, a portion of a second one of the patterned second conductive trace features 124, and a portion of a second one of the second conductive via features 126. As best shown in FIGS. 1D, 1F, and 1G, the conductive box shields 120 each provide contiguous metal shielding that surrounds the respective pairs of conductive signal traces 131, 132 and 133, 134 from the respective first ends near the connection to the respective the conductive structures 119 (FIGS. 1F and 1G) of the semiconductor die 118 to the respective second ends near the connection to the respective leads 109. As discussed further below in connection with FIG. 10, this provides enhanced shielding for the protected differential signal channels for improved EMI performance and reduced crosstalk when the electronic device 100 is powered and operating.

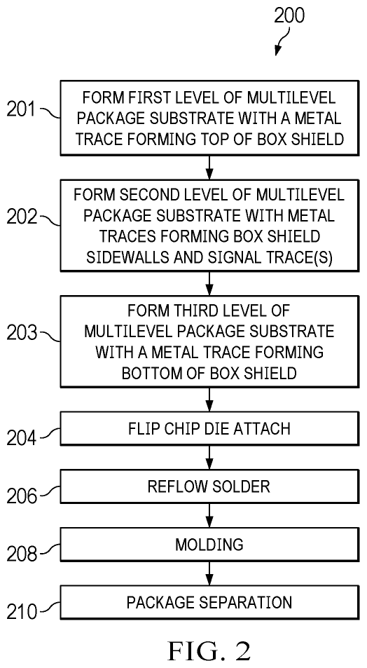

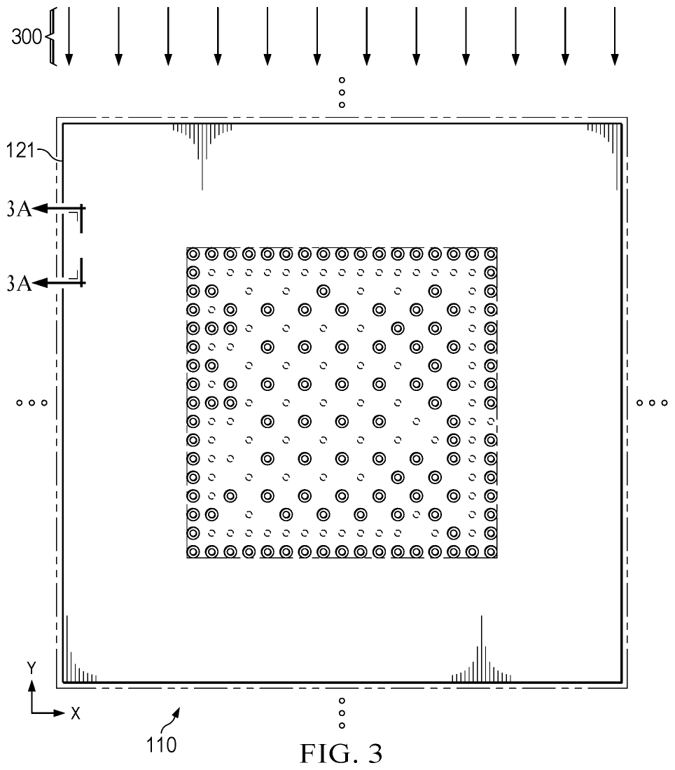

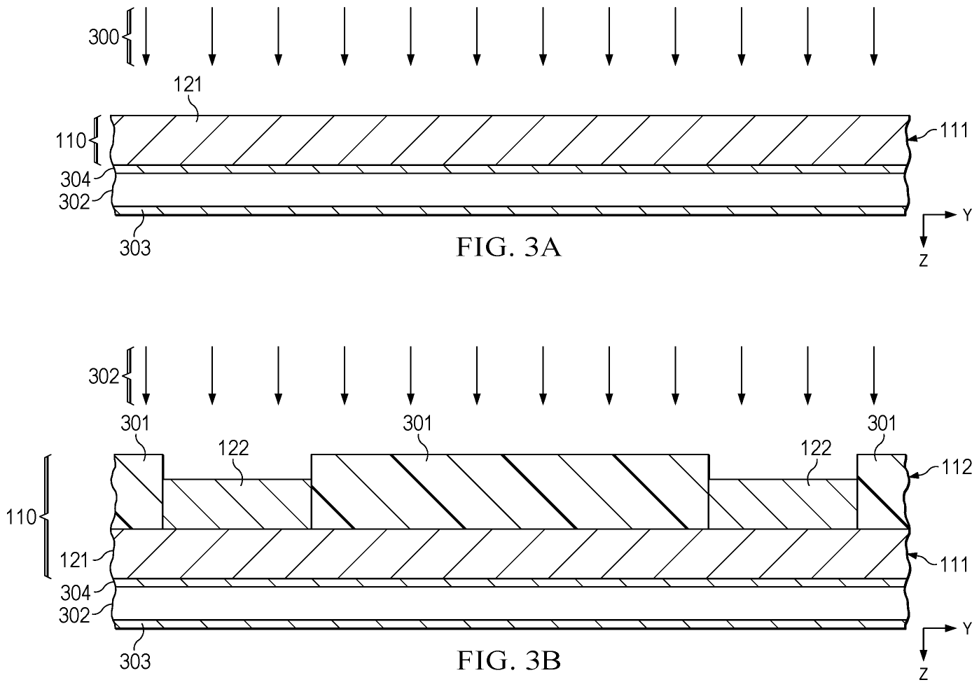

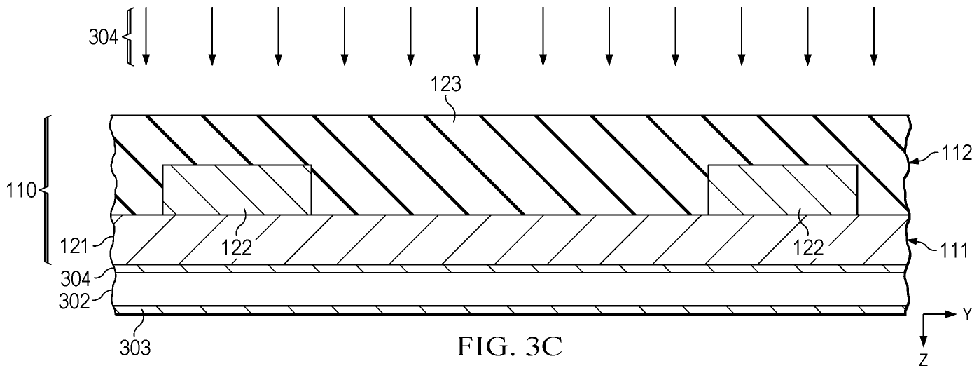

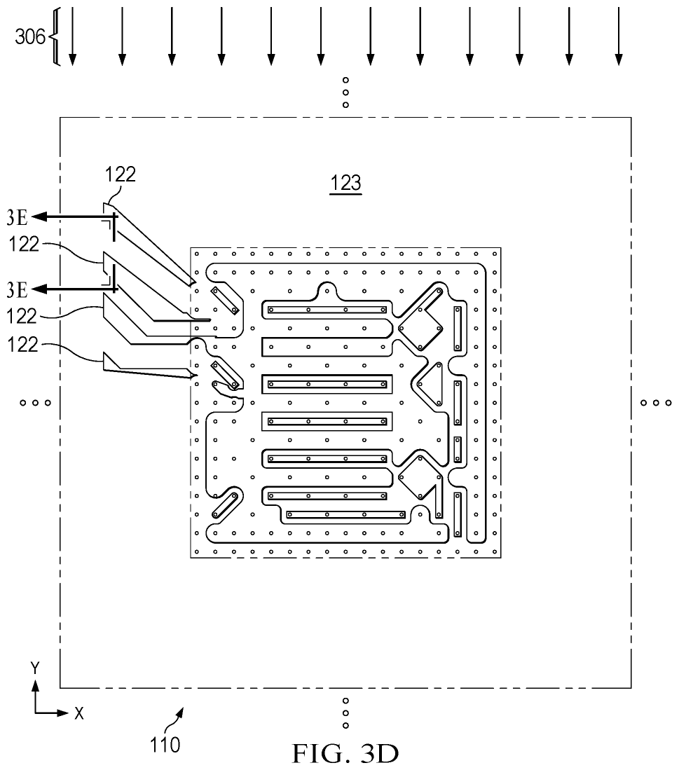

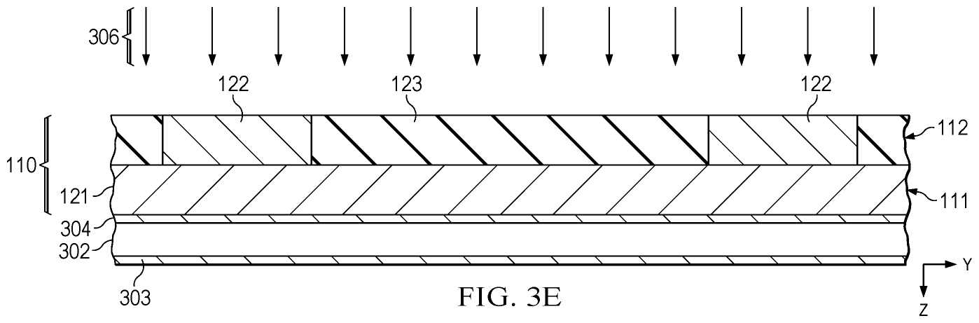

Referring also to FIGS. 2-9, FIG. 2 shows a method 200 of fabricating an electronic device with a box shield in a multilevel package substrate, and FIGS. 3-9 show the example electronic device 100 undergoing fabrication processing according to the method 200. The method 200 includes forming a multilevel package substrate 110 at 201-203. In this example, electroplating steps are used to form patterned metal trace features and patterned metal via features, followed by compression molding of dielectric (e.g., insulator) material and planarization for each level of the multilevel package substrate 110 of FIGS. 1-1G described above. The multilevel package substrate 110 provided and/or manufactured at 201-203 in FIG. 2 includes the above-described features with multiple trace and via levels. In one implementation, the multilevel package substrate 110 is fabricated in a separate fabrication process and is provided as an input component (e.g., a panel or strip with rows and columns of unit areas) to a different manufacturing process for packaging along with the semiconductor die 118. In another implementation, a single fabrication process creates the multilevel package substrate 110 and includes further processing to manufacture packaged semiconductor devices such as the electronic device 100.

FIGS. 3-5F show the multilevel package substrate 110 undergoing fabrication processing as a panel or array with multiple unit areas. At 201 in FIG. 2, the method 200 includes forming the first level (L1) of the multilevel package substrate 110, with a metal trace feature forming the top of the conductive box shield 120. The first level fabrication at 201 includes forming the first trace layer 111 with the patterned first conductive trace features 121, where the shield top includes a portion of a first one of the first conductive trace features 121. In the illustrated example, the multilevel package substrate fabrication at 201-203 includes forming the first level L1 with patterned conductive metal trace and via features 121 and 122 and a dielectric layer 123 on a carrier structure 302, and subsequently forming the second level L2 on the first level at 202 and forming the third level L3 on the second level L2, after which the carrier structure is removed from the first level L1. Following the fabrication of multiple rows and columns of the substrate panel array, the panel array is used as a component in the fabrication of a panel or array of the electronic devices 100.

FIG. 3 shows a top plan view of the multilevel package substrate 110 undergoing an electroplating process 300 to form the patterned first trace layer 111 in the first level L1, and FIG. 3A shows a partial sectional side elevation view taken along line 3A-3A in FIG. 3. As shown in FIGS. 3 and 3A, the first level formation at 201 starts with forming the first trace layer 113 using a stainless-steel or other suitable carrier 302 (FIG. 3A), such as a panel or strip with multiple prospective multilevel package substrate sections or unit areas, one of which is shown in FIG. 3. The illustrated example includes conductive metal features 121 formed by an electroplating process 300, where the conductive metal features 121 are or include copper. In other implementations, a different conductive metal can be used, such as aluminum or metals that include aluminum, etc. The carrier structure 302 in the example of FIG. 3A includes thin copper seed layers 303 and 304 formed by a blanket deposition process (not shown) such as chemical vapor deposition (CVD) on the respective bottom and top sides of the carrier structure 302 to facilitate subsequent electroplating via the process 300. The electroplating process 300 deposits copper onto the upper copper seed layer 304 in the portions of the topside of the carrier structure that are exposed through a patterned plating mask (not shown in the portion illustrated in FIG. 3A) to form the first patterned conductive trace features 121 in the first level L1.

The first level formation continues with forming the first via layer 112 with patterned first conductive via features 122 on the first conductive trace features 121. FIG. 3B shows a partial sectional side elevation view taken along the line 3A-3A in FIG. 3 of the multilevel package substrate undergoing another electroplating process 302 that forms the patterned first via layer 112 with the first conductive via features 122 in the first level of the multilevel package substrate 110 using a patterned plating mask 301.

As further shown in FIGS. 3C-3E, the first level formation also includes performing a dielectric compression molding process 304 that forms the first dielectric layer 123 on and between the first conductive trace features 121 and between the first conductive via features 122. In other implementations, a different dielectric layer formation process can be used, such as a deposition process (not shown). FIG. 3C is a partial sectional side elevation view taken along line 3A-3A in FIG. 3 of the multilevel package substrate 110 undergoing the compression molding process 304. The compression molding process 304 forms the molded dielectric layer features 123 in FIG. 3C to an initial thickness that covers the first conductive trace features 121 and the first conductive via features 122. A grinding or other planarization process 306 is performed in FIGS. 3D and 3E, which grinds upper portions of the molded dielectric material 123 and exposes the upper portions of the first conductive via features 122 as shown in FIG. 3E. FIG. 3D shows a top plan view of the first level of the multilevel package substrate undergoing the planarization process 306 to planarize the top side of the first level L1 of the multilevel package substrate 110, and FIG. 3E shows a partial sectional side elevation view taken along line 3E-3E in FIG. 3D. In another example, a chemical etch is used. In a further example, a chemical mechanical polishing (CMP) process is used. As shown in FIG. 3E, the first dielectric layer 123 encloses a portion of the first conductive trace features 121.

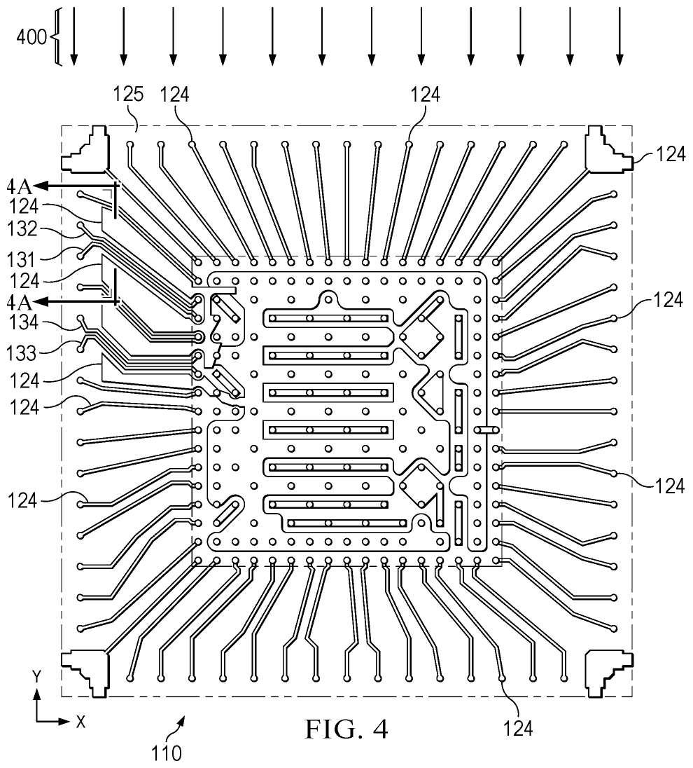

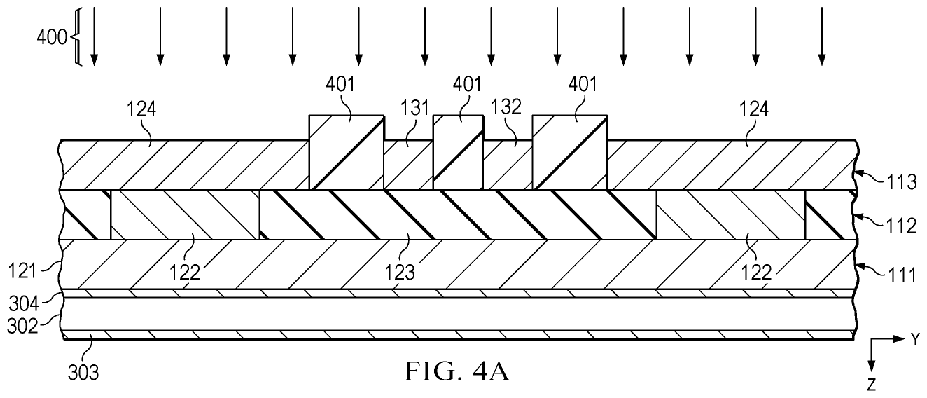

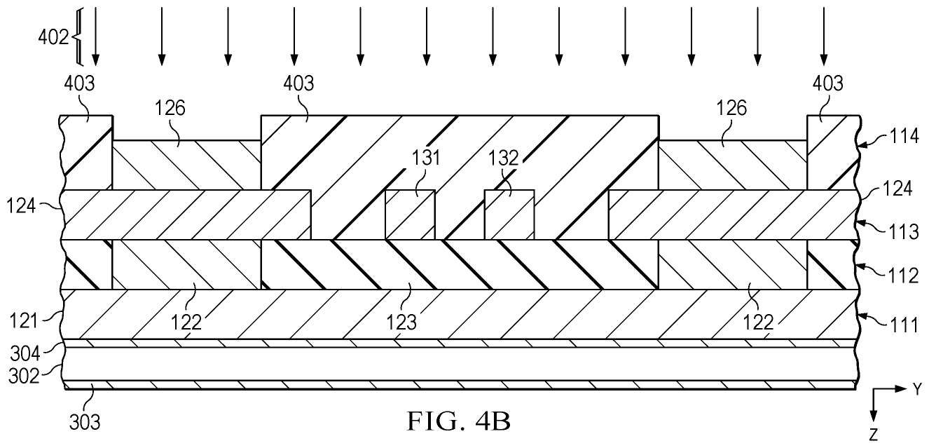

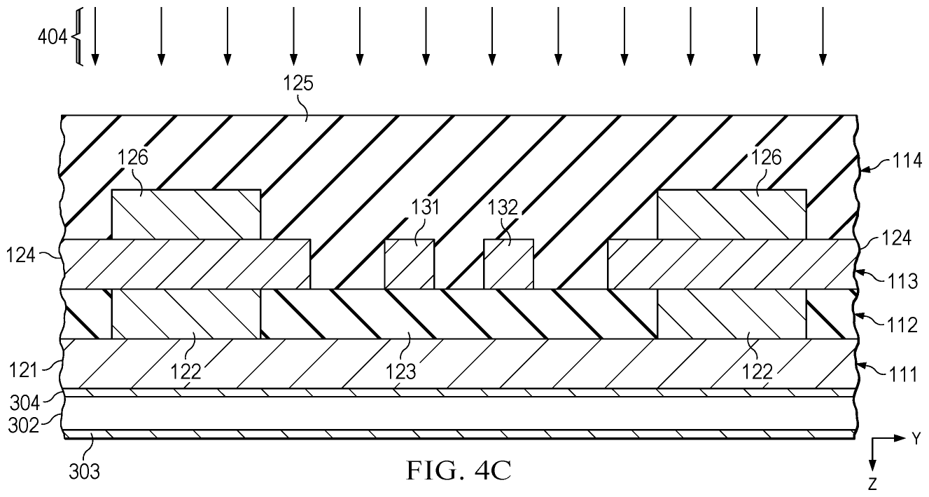

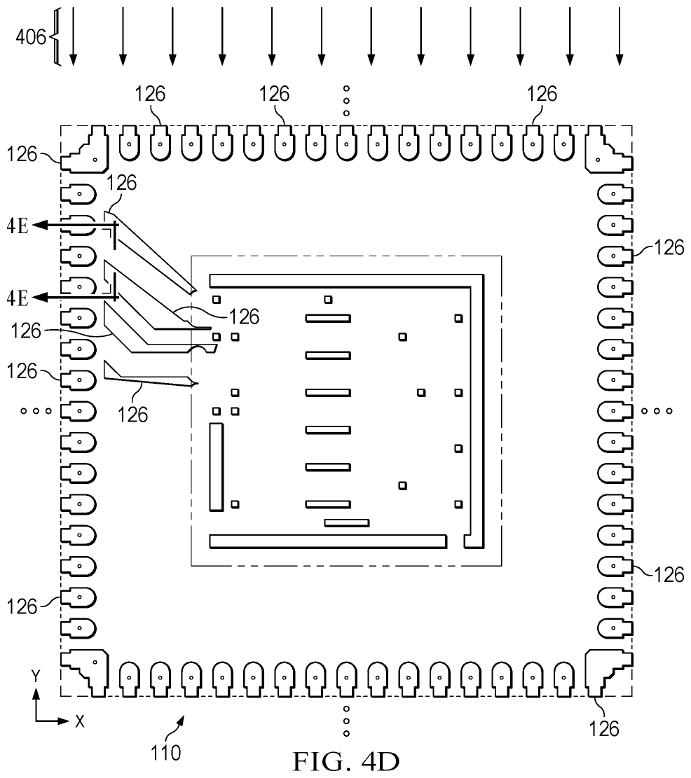

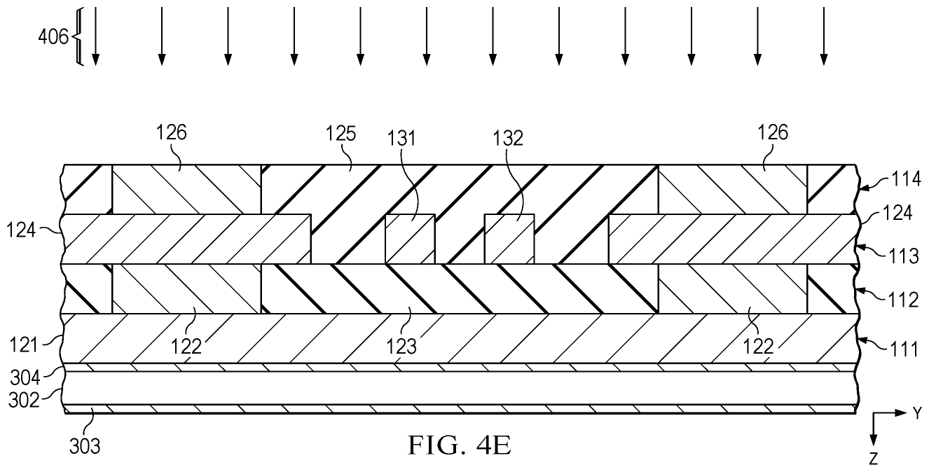

The method 200 of FIG. 2 continues at 202 with forming the second level of the multilevel package substrate 110 with metal traces and vias forming portions of the box shield sidewalls and signal traces (e.g., signal traces 131-134). FIGS. 4-4E show formation of the second level on the first level, including forming the second trace layer 113 via another copper electroplating process 400 using a plating mask 401 (FIG. 4A, taken along line 4A-4A in the top view of FIG. 4). As shown in FIGS. 4 and 4A, the electroplating process 400 forms the electroplated second trace layer 113 that includes the patterned second conductive trace features 124, 131, 132 on the first conductive via features 122 and on the first dielectric layer 123 of the first level. The first shield sidewall in the illustrated portion of FIG. 4A includes a portion of a first one of the patterned second conductive trace features 124, and the second shield sidewall including a portion of a second one of the patterned second conductive trace features 124. In addition, the illustrated conductive signal traces 131 and 132 include further ones of the patterned second conductive trace features.

The second level formation continues in FIG. 4B (also taken along line 4A-4A in FIG. 4) with another electroplating process 402 using a further plating mask 403. The electroplating process 402 forms the second via layer 114 including the patterned second conductive via features 126 on the second conductive trace features 124, 131, 132. In the illustrated portion, the first shield sidewall includes a portion of a first one of the second conductive via features 126, the second shield sidewall includes a portion of a second one of the second conductive via features 126, and the conductive signal traces 131 and 132 include further ones of the second conductive via features in the illustrated portion of the second level.

As further shown in FIGS. 4C-4E, the second level formation also includes performing another dielectric compression molding process 404 in FIG. 4C that forms the second dielectric layer 125 on and between the second conductive trace features 124, 131, 132 and between the second conductive via features 126. In other implementations, a different dielectric layer formation process can be used, such as a deposition process (not shown). FIG. 4C is a partial sectional side elevation view taken along line 4A-4A in FIG. 4 of the multilevel package substrate 110 undergoing the compression molding process 404. The compression molding process 404 forms the second dielectric layer features 125 in FIG. 4C to an initial thickness that covers the second conductive trace features 124, 131, and 132 and the second conductive via features 126.

In FIGS. 4D and 4E, a grinding or other planarization process 406 is performed that grinds upper portions of the molded dielectric material 125 and exposes the upper portions of the second conductive via features 126 as shown in FIG. 4E. FIG. 4D shows a top plan view of the second level of the multilevel package substrate undergoing the planarization process 406 to planarize the top side of the second level, and FIG. 4E shows a partial sectional side elevation view taken along line 4E-4E in FIG. 4D. In another example, a chemical etch is used. In a further example, a chemical mechanical polishing (CMP) process is used.

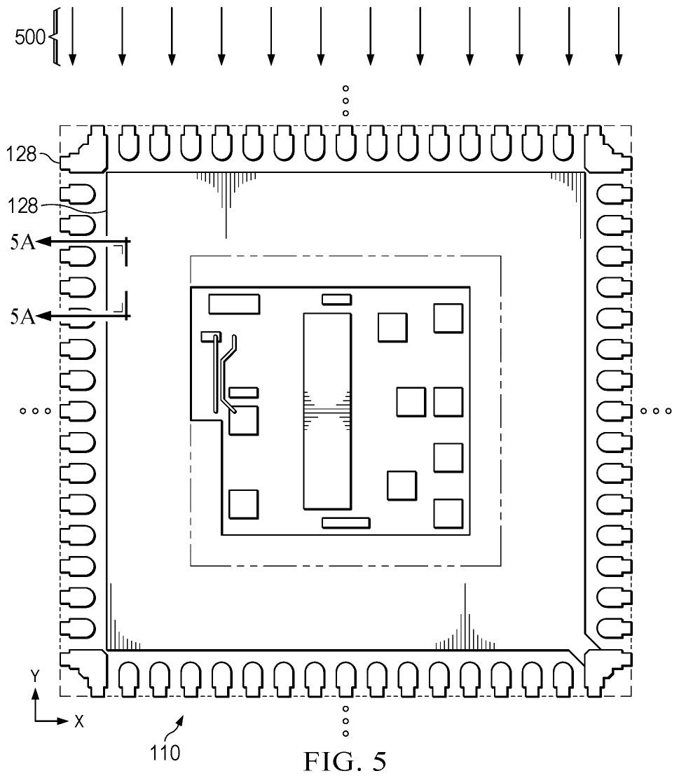

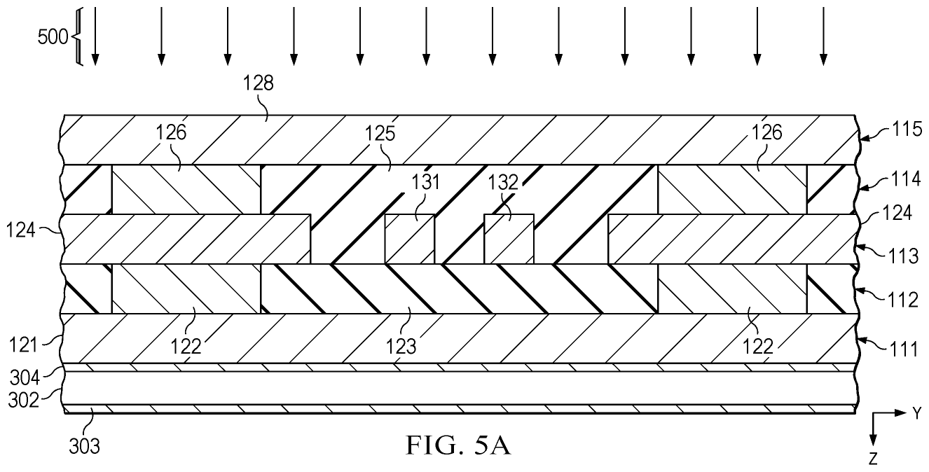

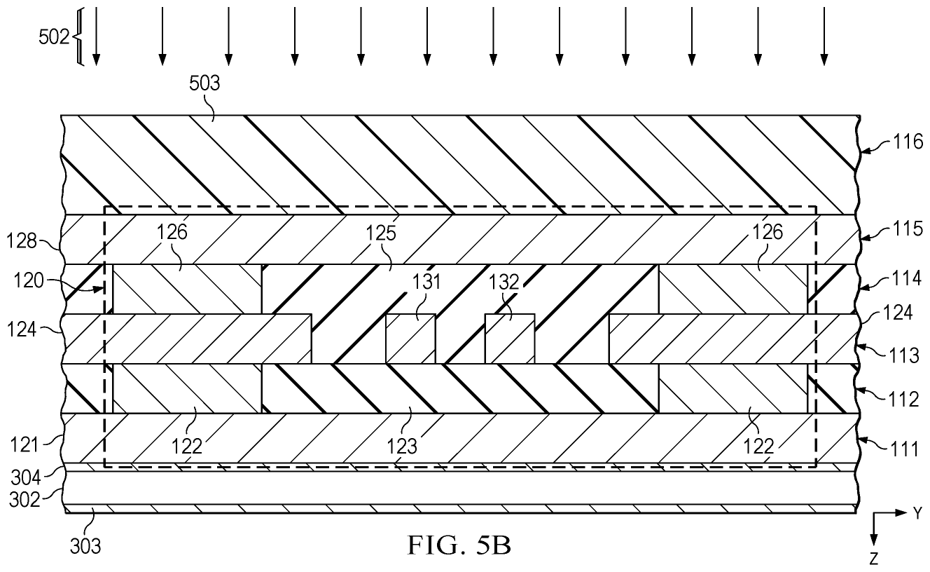

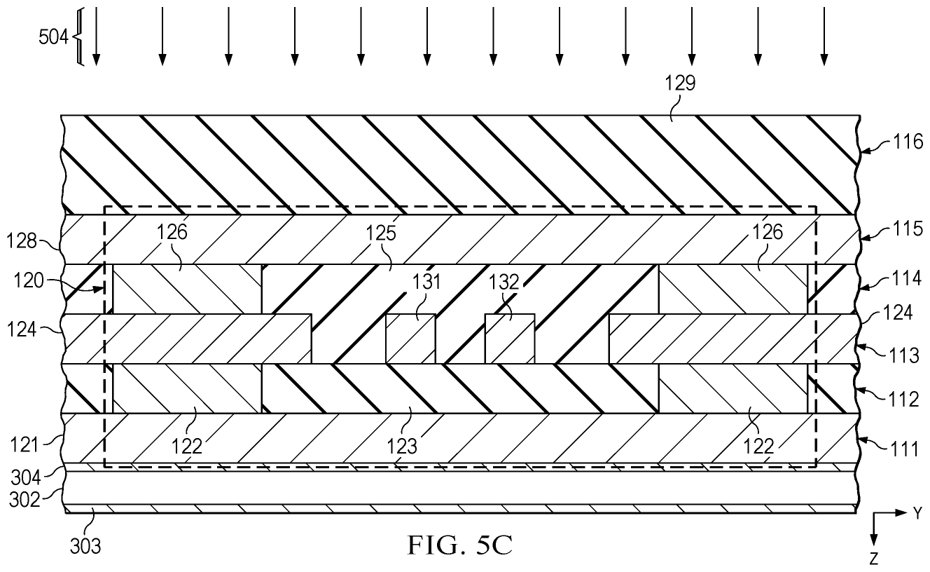

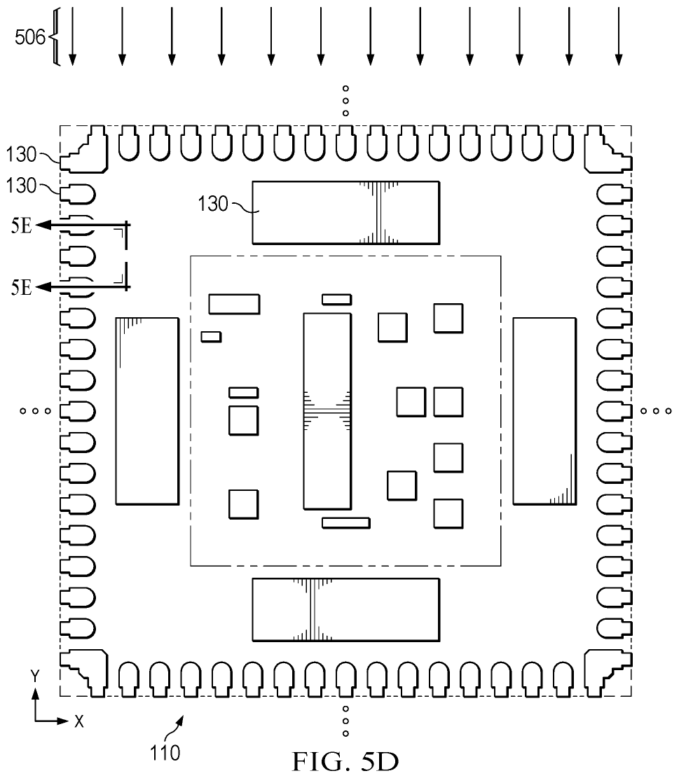

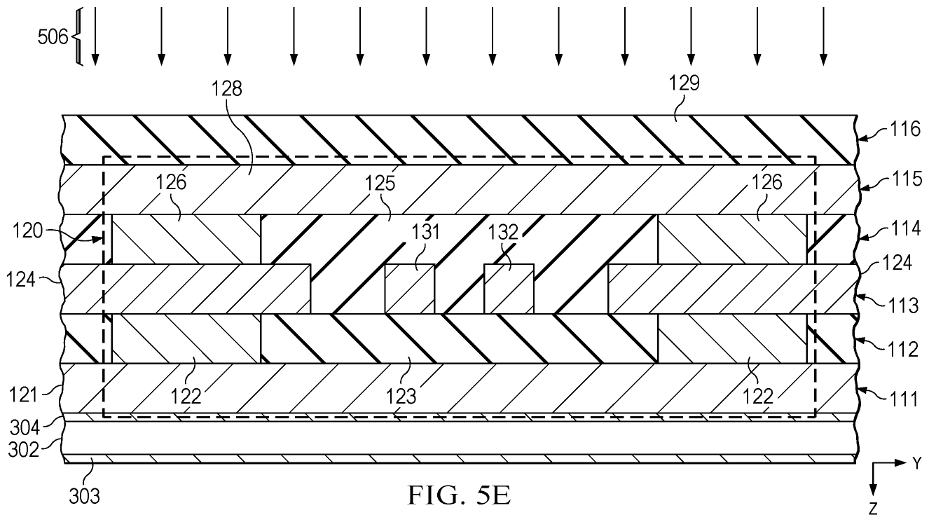

The method 200 in FIG. 2 further includes forming the third level of the multilevel package substrate 110 at 203. FIGS. 5-5E show formation of the third level on the second level, including forming the third trace layer 115 via another copper electroplating process 500 using a plating mask (not shown), where FIG. 5A is taken along line 5A-5A in the top view of FIG. 5. As shown in FIGS. 5 and 5A, the electroplating process 500 forms the electroplated third trace layer 115 that includes the patterned third conductive trace features 128 including a portion that forms the shield bottom on the second conductive via features 126 and on the second dielectric layer 125 of the second level. The third level formation in one example also includes performing another electroplating process 502 in FIG. 5B using a further plating mask 503 to form the third via layer 116 including the patterned third conductive via features 130 (e.g., FIGS. 1D and 1G above) on portions of the third conductive trace features 128, for example, and forming the device leads 109. In the illustrated portion, the first shield sidewall includes a portion of a first one of the third conductive via features 126, the third shield sidewall includes a portion of a third one of the third conductive via features 126, and the conductive signal traces 131 and 132 include further ones of the third conductive via features in the illustrated portion of the third level. As further shown in FIG. 5C, the third level formation also includes performing another dielectric compression molding process 504 that forms the third dielectric layer 129 on and between the third conductive trace features 128 and between the third conductive via features 130. In other implementations, a different dielectric layer formation process can be used, such as a deposition process (not shown). FIG. 5C is a partial sectional side elevation view taken along line 5A-5A in FIG. 5 of the multilevel package substrate 110 undergoing the compression molding process 504. The compression molding process 504 forms the third dielectric layer features 129 to an initial thickness in FIG. 5C that covers the third conductive trace features 128 and the third conductive via features 130.

In FIGS. 5D and 5E, a grinding or other planarization process 506 is performed that grinds upper portions of the molded dielectric material 129 and exposes the upper portions of the third conductive via features 130 as shown in FIG. 5E. FIG. 5D shows a top plan view of the third level of the multilevel package substrate undergoing the planarization process 506 to planarize the top side of the third level, and FIG. 5E shows a partial sectional side elevation view taken along line 5E-5E in FIG. 5D. In another example, a chemical etch is used. In a further example, a chemical mechanical polishing (CMP) process is used. A removal process 510 is performed in FIG. 5F to remove the carrier structure 302 and any remaining portions of the seed layer 304.

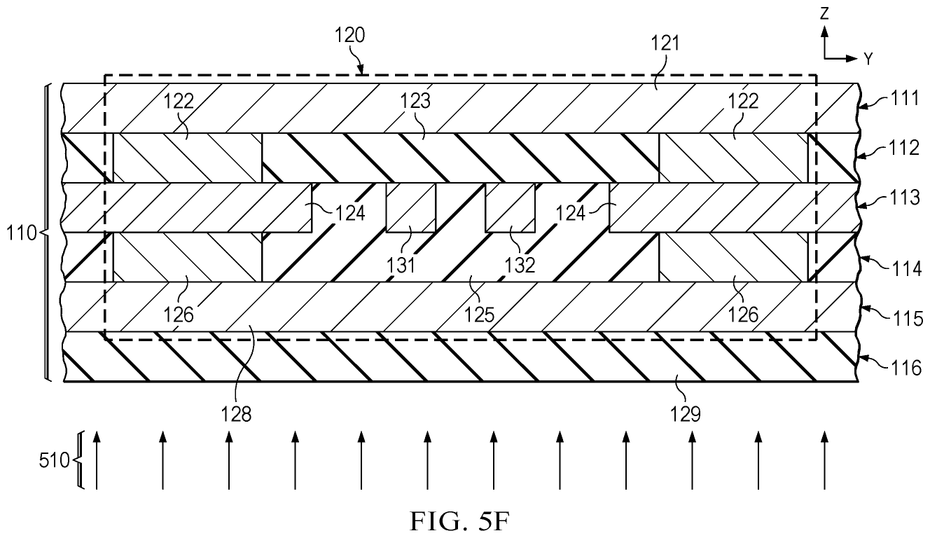

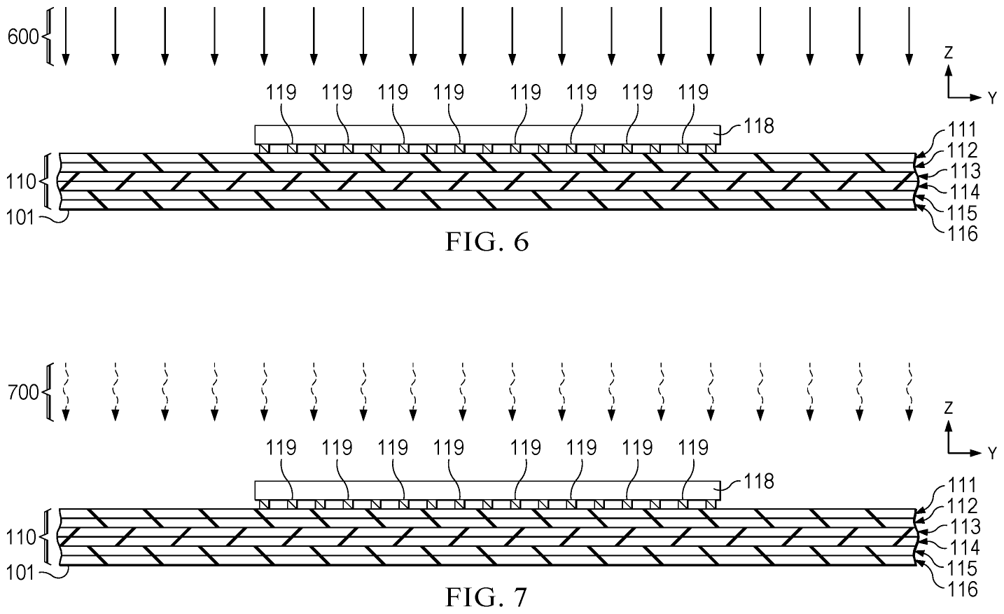

The method continues at 204 in FIG. 2 with die attach processing. FIG. 6 shows a side view of one example that includes performing a flip chip die attach process 600 that attaches the semiconductor die 118 to the top side of the multilevel package substrate 110. The semiconductor die 118 can be attached to the top side of the multilevel package substrate 110 using any suitable techniques and materials. In one example, the semiconductor die 110 is adhered to the top side of the multilevel package substrate 110 using an adhesive (not shown). In the illustrated example, the die attach process 600 includes placement of the semiconductor die 118 using automated pick and place equipment (not shown). In one implementation, bottoms of the conductive features 119 (e.g., copper pillars) of the semiconductor die 118 are dipped in solder, and the semiconductor die 118 is positioned as shown in FIG. 6 with the copper pillars 119 and associated solder placed on respective portions of first conductive trace features 121 of the multilevel package substrate 110.

The method 200 continues at 206 in FIG. 2 with electrical connection of the conductive features 119 of the semiconductor die 118 to the respective first conductive trace features 121 on the top side of the multilevel package substrate 110. In the illustrated example, a thermal reflow process 700 is performed in FIG. 7 (e.g., at 206 of FIG. 2). The reflow process 700 is a thermal process that heats and reflows the solder to form solder connections between the conductive copper pillars 119 of the semiconductor die 118 and the respective metal trace features 121 of the first trace layer 111 of the multilevel package substrate 110.

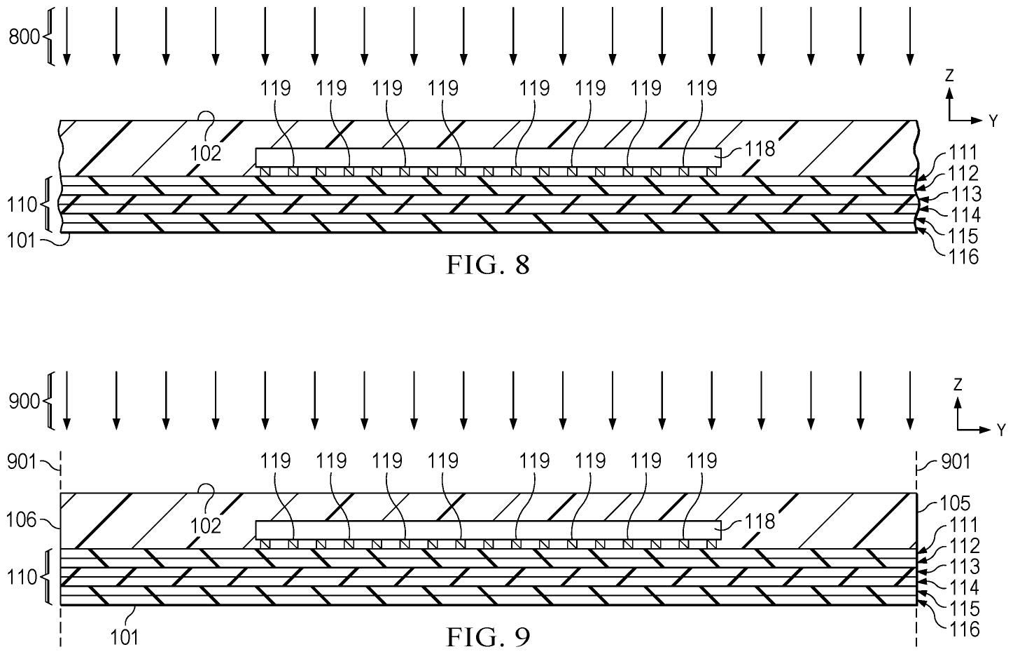

The method 200 continues at 208 in FIG. 2 forming the package structure 108, for example, by molding operations. FIG. 8 shows one example, in which a molding process 800 is performed that forms the molded plastic package structure 108 that encloses the semiconductor die 118 and the exposed top side of the multilevel package substrate 110. The method 200 in one example also includes package separation at 210 in FIG. 2. FIG. 9 shows one example, in which a package separation process 900 is performed that separates individual packaged electronic devices 100 from a starting panel array, for example, using saw or laser cutting, chemical etching, etc. As shown in FIG. 9, the separation process 900 in one example includes cutting along lines 901 that are parallel to the second direction Y to form the illustrated device sides 105 and 106, and similar cutting operations are used along cut lines parallel to the first direction X to form the front and back sides 103 and 104 (not shown in FIG. 9). The resulting packaged electronic device 100 is shown in FIGS. 1-1G as discussed above.

FIG. 10 shows a graph 1000 with comparative crosstalk performance curves for flip chip, chip scale package (FCCSP) electronic devices with controlled differential transmission impedance to 100 ohms, including a first curve 1001 that shows the Y1 crosstalk performance in dB for the example electronic device 100 as a function of frequency. The graph 1000 also includes a second curve 1002 representing the crosstalk performance for another electronic device using drilled copper vias (not shown) to form substrate shield sidewalls with a cage type profile having openings between upper and lower ground planes. A third curve 1003 in FIG. 10 shows comparative crosstalk performance for a further device having conductive signal traces with only a single underlying ground plane, As shown in the graph 1000, the conductive box shield 120 of the described examples provides significant improvement in crosstalk performance shown by the curve 1001, including a 6 dB improvement over the second curve 1002 and a 12 dB improvement over the third curve 1003 at a frequency of 10 GHz. The described examples provide shielding performance benefits with no added manufacturing cost or complexity, with the crosstalk and EMI performance similar to that of 360 degree true coaxial shielded cables, which can be achieved in any type of high speed circuit systems and applications.

Modifications are possible in the described examples, and other implementations are possible, within the scope of the claims.

What is claimed is:

1. An electronic device, comprising:
a multilevel package substrate having a first level, a second level, a third level, a conductive signal trace that extends in the second level, and a conductive box shield that surrounds a portion of the conductive signal trace;
a semiconductor die attached to the multilevel package substrate and having a conductive structure coupled to an end of the conductive signal trace; and
a package structure that encloses the semiconductor die and a portion of the multilevel package substrate.

2. The electronic device of claim 1, wherein the multilevel package substrate has a conductive lead coupled to a second end of the conductive signal trace.

3. The electronic device of claim 1, wherein:
the first level includes a first trace layer with patterned first conductive trace features, a first via layer with patterned first conductive via features, and a first dielectric layer that extends on and between the first conductive trace features and between the first conductive via features;
the second level includes a second trace layer with patterned second conductive trace features, a second via layer with patterned second conductive via features, and a second dielectric layer that extends on and between the second conductive trace features and between the second conductive via features;
the third level includes a third trace layer with patterned third conductive trace features, and a third dielectric layer that extends on and between the third conductive trace features;
the conductive box shield includes contiguous conductive metal structures that form a shield top, a shield bottom, and opposite first and second shield sidewalls;
the shield top includes a portion of a first one of the first conductive trace features;
the shield bottom includes a portion of a first one of the third conductive trace features;
the first shield sidewall includes a portion of a first one of the first conductive via features, a portion of a first one of the patterned second conductive trace features, and a portion of a first one of the second conductive via features; and
the second shield sidewall includes a portion of a second one of the first conductive via features, a portion of a second one of the patterned second conductive trace features, and a portion of a second one of the second conductive via features.

4. The electronic device of claim 3, wherein:
the third level includes a third via layer with patterned third conductive via features;
the third dielectric layer extends between the third conductive via features; and
the multilevel package substrate has a conductive lead that includes a first one of the third conductive via features.

5. The electronic device of claim 4, wherein the conductive lead is coupled to a second end of the conductive signal trace.

6. The electronic device of claim 4, wherein the conductive signal trace includes a third one of the patterned second conductive trace features.

7. The electronic device of claim 6, wherein:
the multilevel package substrate has a second conductive signal trace that extends in the second level and is spaced apart from the conductive signal trace;
the second conductive signal trace includes a fourth one of the patterned second conductive trace features;
the semiconductor die has a second conductive structure coupled to an end of the second conductive signal trace; and
the conductive box shield surrounds a portion of the second conductive signal trace.

8. The electronic device of claim 1, wherein:
the multilevel package substrate has a second conductive signal trace that extends in the second level and is spaced apart from the conductive signal trace;
the semiconductor die has a second conductive structure coupled to an end of the second conductive signal trace; and
the conductive box shield surrounds a portion of the second conductive signal trace.

9. The electronic device of claim 8, wherein the multilevel package substrate has a first conductive lead coupled to a second end of the conductive signal trace, and a second conductive lead coupled to a second end of the second conductive signal trace.

10. A multilevel package substrate, comprising:
a first level;
a second level on the first level and having a conductive signal trace;
a third level on the second level; and
a conductive box shield including contiguous conductive metal structures of the first, second, and third levels that surround a portion of the conductive signal trace.

11. The multilevel package substrate of claim 10, further comprising a conductive lead coupled to an end of the conductive signal trace.

12. The multilevel package substrate of claim 10, wherein:
the first level includes a first trace layer with patterned first conductive trace features, a first via layer with patterned first conductive via features, and a first dielectric layer that extends on and between the first conductive trace features and between the first conductive via features;
the second level includes a second trace layer with patterned second conductive trace features, a second via layer with patterned second conductive via features, and a second dielectric layer that extends on and between the second conductive trace features and between the second conductive via features; and
the third level includes a third trace layer with patterned third conductive trace features, and a third dielectric layer that extends on and between the third conductive trace features.

13. The multilevel package substrate of claim 12, wherein:
the conductive box shield includes a shield top, a shield bottom, and opposite first and second shield sidewalls;
the shield top includes a portion of a first one of the first conductive trace features;
the shield bottom includes a portion of a first one of the third conductive trace features;
the first shield sidewall includes a portion of a first one of the first conductive via features, a portion of a first one of the patterned second conductive trace features, and a portion of a first one of the second conductive via features; and
the second shield sidewall includes a portion of a second one of the first conductive via features, a portion of a second one of the patterned second conductive trace features, and a portion of a second one of the second conductive via features.

14. The multilevel package substrate of claim 12, wherein:
the third level includes a third via layer with patterned third conductive via features;
the third dielectric layer extends between the third conductive via features; and
the multilevel package substrate has a conductive lead that includes a first one of the third conductive via features.

15. The multilevel package substrate of claim 12, wherein the conductive signal trace includes a third one of the patterned second conductive trace features.

16. The multilevel package substrate of claim 10, further comprising a second conductive signal trace that extends in the second level and is spaced apart from the conductive signal trace, wherein the conductive box shield surrounds a portion of the second conductive signal trace.

17. A method of fabricating an electronic device, the method comprising:
forming a first level of a multilevel package substrate having a conductive box shield that surrounds a portion of a conductive signal trace and includes a shield top, a shield bottom, and opposite first and second shield sidewalls, including: forming a first trace layer with patterned first conductive trace features, the shield top including a portion of a first one of the first conductive trace features; forming a first via layer with patterned first conductive via features on the first conductive trace features; and forming a first dielectric layer on and between the first conductive trace features and between the first conductive via features;
forming a second level on the first level, including: forming a second trace layer with patterned second conductive trace features on the first conductive via features and on the first dielectric layer, the first shield sidewall including a portion of a first one of the patterned second conductive trace features, the second shield sidewall including a portion of a second one of the patterned second conductive trace features, the conductive signal trace includes a third one of the patterned second conductive trace features: forming a second via layer with patterned second conductive via features on the second conductive trace features, the first shield sidewall including a portion of a first one of the second conductive via features, the second shield sidewall including a portion of a second one of the second conductive via features; and forming a second dielectric layer on and between the second conductive trace features and between the second conductive via features; and
forming a third level on the second level, including: forming a third trace layer with patterned third conductive trace features on the second conductive via features and on the second dielectric layer, the shield bottom including a portion of a first one of the third conductive trace features; and forming a third dielectric layer on and between the third conductive trace features.

18. The method of claim 17, wherein:
forming the third level includes forming a third via layer with patterned third conductive via features on the third conductive trace features, a first one of the third conductive via features forming a conductive lead; and
the third dielectric layer extends between the third conductive via features.

19. The method of claim 17, wherein:
a fourth one of the patterned second conductive trace features forms a second conductive signal trace that is spaced apart from the conductive signal trace; and
the conductive box shield surrounds a portion of the second conductive signal trace.

20. The method of claim 17, further comprising:
attaching a semiconductor die to the multilevel package substrate;
electrically coupling a conductive structure of the semiconductor die to an end of the conductive signal trace; and
forming a package structure that encloses the semiconductor die and a portion of the multilevel package substrate.
